(19) United States
(12) Patent Application Publication
(10) Pub. No.: US 2020/0006190 A1
(43) Pub. Date: Jan. 2, 2020

(54) HEAT TRANSFER STRUCTURE, POWER ELECTRONICS MODULE, COOLING ELEMENT, METHOD OF MANUFACTURING A HEAT TRANSFER STRUCTURE AND METHOD OF MANUFACTURING A POWER ELECTRONICS COMPONENT

(71) Applicant: ABB Schweiz AG, Baden (CH)

(72) Inventors: Jorma Manninen, Vantaa (FI); Mika Silvennoinen, Espoo (FI); Kjell Ingman, Sipoo (FI)

(21) Appl. No.: 16/023,252

(22) Filed: Jun. 29, 2018

(51) Int. Cl. H01L 23/373; H01L 23/367; H05K 7/20; H01L 25/07; H01L 21/48

(52) U.S. Cl. CPC H01L 23/3735; H01L 23/3675; H01L 21/4882; H01L 25/072; H05K 7/209

(57) ABSTRACT

The present application relates to a heat transfer structure, power electronics module, cooling element and methods of manufacturing a heat transfer structure and a power electronics component. A heat transfer structure is utilized in a power electronics module. The heat transfer structure includes a metallic body and a carbon based insert.

### FIELD OF THE INVENTION

The present invention relates to a heat transfer structure, power electronics module, cooling element and methods of manufacturing a heat transfer structure and a power electronics component.

### BACKGROUND OF THE INVENTION

Power electronics components, such as single power electronics components or power electronic modules, are commonly used in high powered devices for switching high currents and operating on high voltages. With single power electronics components reference is made to high power thyristors and diodes, for example. Power electronics modules contain multiple of switch components which are situated in a same component housing and typically internally connected to each other to provide a certain circuit structure.

Power electronics modules are used, for example, for producing certain power conversion circuits, such as inverters and converters. An example of a power electronics module contains two IGBTs (Insulated Gate Bi-polar Transistors) which are connected in series inside the module. Other examples may include bridge topologies or parts of bridge topologies which are readily electrically connected inside the module.

Power electronics modules or single power electronics components may also comprise a base plate which is typically made of copper. The purpose of the base plate is to conduct the heat generated by the semiconductors to a cooling device, such as heatsink. The surface of the base plate is typically a substantially planar surface to which a heatsink can be attached. The heatsink is further dimensioned to take into account the amount of heat generated by the semiconductor components in the module.

FIG. 1 shows an example of a cross-section of a power electronics module 1 attached to a heatsink 2. The power electronics module of the example comprises two semiconductor chips 11, 12 which are soldered to a substrate, such as a direct copper bonding (DCB) structure. The DCB structure of the example has two copper plates 3 and a ceramic layer 4 between the copper plates 3. The DCB structure is soldered with a solder layer 5 on the top of a copper base plate 7 of the module. The module further comprises a housing 6 which is shown with a dash-dot line surrounding the DCB structure and the chips.

The module of the example of FIG. 1 is attached to a heatsink such that a thermal interface material 8 is positioned between the base plate of the module and the base plate of the heatsink. The purpose of the thermal interface material is to transfer the heat from the module's base plate to the heatsink as effectively as possible. It should be noted that FIG. 1 is provided only to show an example of structure of power electronic module attached to a heatsink. It is clear that other kinds of structures exist.

Power electronics module's internal electronics packing density increases gradually with advanced construction materials and manufacturing methods. This is leading to more challenging module external cooling solutions as devices are able to create very high, over 35 W/cm², hot spots to the heatsink surface.

In view of cooling the situation is most demanding when the module is operated at its maximum current and voltage level i.e. at maximum power. In this condition the conventional aluminium heat sinks' baseplate spreading thermal resistance is too high for the module base plate high heat spots. That is, a conventional aluminium heatsink is not able to spread the heat transferred from the baseplate of the module fast enough. This results in both higher heatsink-to-baseplate temperatures and chip-to-junction temperatures accordingly. Although novel components may allow higher junction temperatures than before due to novel chip material, the component may not be fully utilized unless the power electronics module's external cooling in not at appropriate level.

Common power electronics module external cooling solutions include for example aluminium heat sinks. These conventional solutions are quite sufficient for base plate heat loss densities of typical power electronics modules.

More demanding applications with higher base plate heat loss densities, e.g. over 35 W/cm2, require clearly more effective heat transfer from the base plate. Typically heat transfer is increased for example by increasing cooling air flow rate with larger cooling fans, modifying the aluminium heat sink in different ways like. Modification may include adding a copper heat spreading plate in to the base plate or replacing the heatsink aluminium cooling fins with copper fins. More effective cooling arrangements can be obtained by replacing the aluminium heat sink with heat pipe heat sinks or thermosiphon cooling devices.

Common challenge for these more efficient heat sink and cooling designs is that their cost is significantly higher than conventional aluminium heat sink's. The cost increase derives from several issues like more laborious manufacturing, more complex manufacturing, and higher price materials. It would thus be beneficial to manage the centralized heat loss density within the power electronics module and this way enable use of relatively low cost heat sink solutions.

### BRIEF DISCLOSURE OF THE INVENTION

An object of the present invention is to provide a heat transfer structure, a power electronics module, a cooling element and a method of producing a heat transfer structure and a power electronics module so as to solve the above problems. The objects of the invention are achieved by a heat transfer structure, power electronics module, a cooling element and methods which are characterized by what is stated in the independent claims. The preferred embodiments of the invention are disclosed in the dependent claims.

The invention is based on the idea of producing a heat transfer structure which is employed in a power electronics module and cooling element. The heat transfer structure is formed of a metallic body and has a carbon based insert. According to an embodiment, the carbon based insert is formed of carbon based plates or strips and preferably graphite plates or graphene plates. According to an embodiment, the carbon based insert has anisotropic thermal conductivity.

The heat transfer structure is preferably formed such that carbon based insert is partly in the surface of the metallic body. That is, edges of the carbon based plates are at the surface of the metallic body. According to another embodiment, the carbon based insert is fully inside the metallic body.

The heat transfer structure of the invention produces good thermal characteristics. The heat transferred using the metallic body and the heat transfer is enhanced by the carbon based insert. The carbon based insert spreads the heat efficiently inside the metallic body. The thermal properties of the heat transfer structure when employed in a power semiconductor module enable to use the full potential of the power semiconductor switches of the module.

### BRIEF DESCRIPTION OF THE DRAWINGS

In the following the invention will be described in greater detail by means of preferred embodiments with reference to the accompanying drawings, in which

FIG. 1 shows a prior art power electronics module attached to a heatsink;

FIG. 2 shows cross sections of an embodiment of the present invention;

FIG. 3 shows a flowchart of an embodiment;

FIG. 4 shows a power electronics module according to an embodiment; and

FIG. 5 shows a perspective view of an embodiment of the invention.

### DETAILED DESCRIPTION OF THE INVENTION

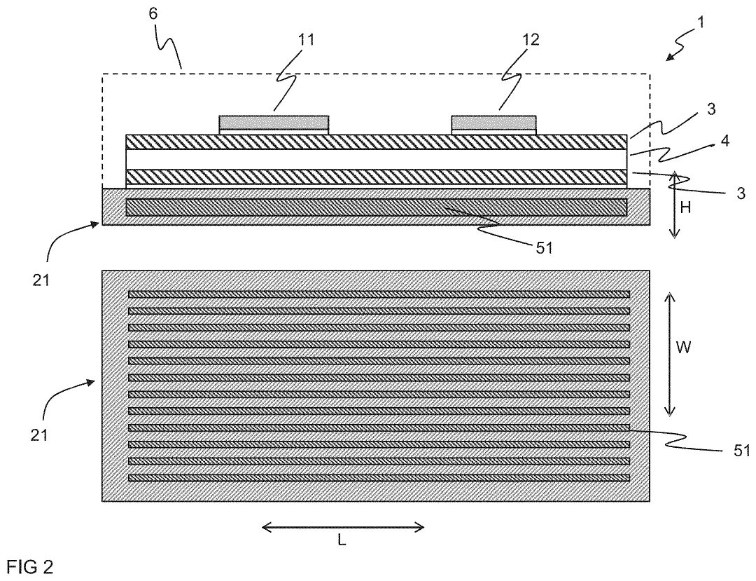

FIG. 2 shows cross sectional views of an embodiment of a power electronics module of the present disclosure. The upper drawing of FIG. 2 shows a cross sectional view as seen from the side of the module and the lower drawing of FIG. 2 shows a cross sectional view revealing the inner structure of the base plate of the power electronics module.

According to the present disclosure the power electronics module comprises at least one power electronics component. In the example of FIG. 2 two power electronics components 11, 12 are shown. Further, the power electronics module comprises a base plate 21 for transferring heat generated by the at least one power electronics component to a cooling device. The base plate of the disclosure is a heat transfer structure comprising a metallic body having a first surface and a second surface. The first and the second surfaces are opposing surfaces, and one of the first surface and the second surface is adapted to receive a heat generating component. In the disclosure, the metallic body of the heat transfer structure comprises a carbon based insert. In the example of FIG. 2, the heat transfer structure is a base plate of a power electronics component.

According to the disclosure, the base plate is a metallic structure with a carbon based insert. The base plate of a power electronics module is a structure that is fastened to a substrate 3,4 of the module and thus a part of the module. One outer surface of a power electronics module is formed of a surface of the base plate, and a cooling device, such as a heatsink, is attached to the surface of the base plate during installation of an electrical device.

According to an embodiment of the invention, the carbon based insert has anisotropic thermal conductivity. With anisotropic thermal conductivity it is referred to a structure which transfers heat more efficiently in one direction than to another direction. Further, according to an embodiment, the thermal conductivity of the core structure of the base plate is highest in a plane defined by the directions of length and height of the base plate. The direction of length being defined as the direction of the longest dimension of the heat transfer structure L and the direction of height H being defined as the direction of normal of the surface of the heat transfer structure. Thus, when the thermal conductivity is highest in a plane defined by the directions of length and height of the base plate, heat is transferred efficiently in the direction of length and height of the base plate. This means further that the heat is not transferred as efficiently in the direction opposite to the mentioned plane, i.e. in the direction of width of the base plate.

According to an embodiment, the carbon based insert comprises carbon based material plates 51 which are arranged at least partly inside the metallic body of the heat transfer structure. The metallic body of heat transfer structure is preferably a copper structure. According to an embodiment carbon based material plates 51 have a length, a width and a height. The length of the carbon based material plates being the greatest dimension and the height being the smallest dimension of the carbon based material plates. The carbon based material plates are further arranged parallel inside the metallic body, such that the direction of length of carbon based material plates correspond to the direction of length of the metallic body and the direction of width of carbon based material plates correspond to the direction of height of the metallic body. With the embodiment, the thermal conductivity of the heat transfer structure is highest in the direction of length of the metallic body and in the direction of height of the metallic body as the carbon based material plates have the longest dimensions in those directions. In FIG. 2 the carbon based material plates are shown completely enclosed by the metallic body. However, the carbon based material plates or strips may be positioned such that one edge of the carbon based material plates are in the surface of the metallic body. That is, the carbon based material plates have one edge which forms part of one surface of the heat transfer structure. In FIG. 2 the carbon based material plates 51 are shown inside the metallic body. Another option would thus be that the carbon based material plates are in connection with the surface which is connected to a DCB structure 3, 4. or with a cooling structure like a heat sink. Naturally, a thermal interface material layer may be employed between a power electronics module and a heat sink, and thus the edges of the carbon based material plates may be in contact with the thermal interface material layer.

When the semiconductor components of a power electronics module are used, the losses in the components or chips 11, 12 generate heat. The heat is transferred through the DCB structure 3, 4 to the base plate. The base plate of the disclosure having a carbon based insert spreads the heat effectively inside the base plate and thus prevents formation of hot-spots in the base plate in the footprint area of the semiconductor chips. With the footprint area of the chips it is referred to the surface area that is directly below chips.

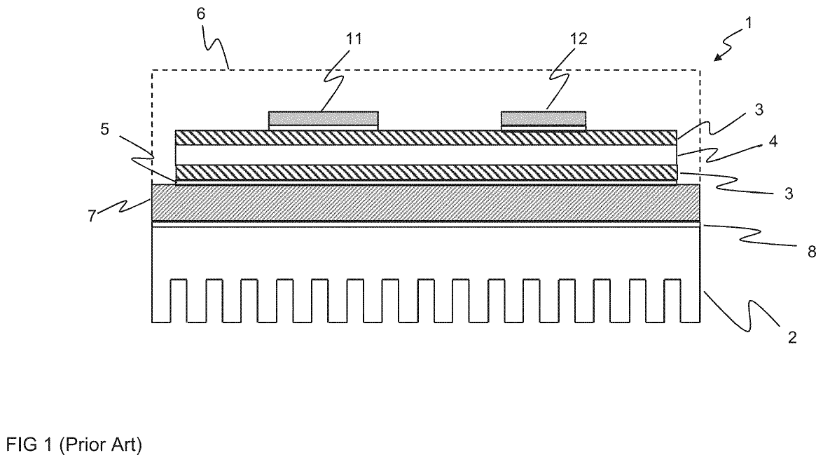

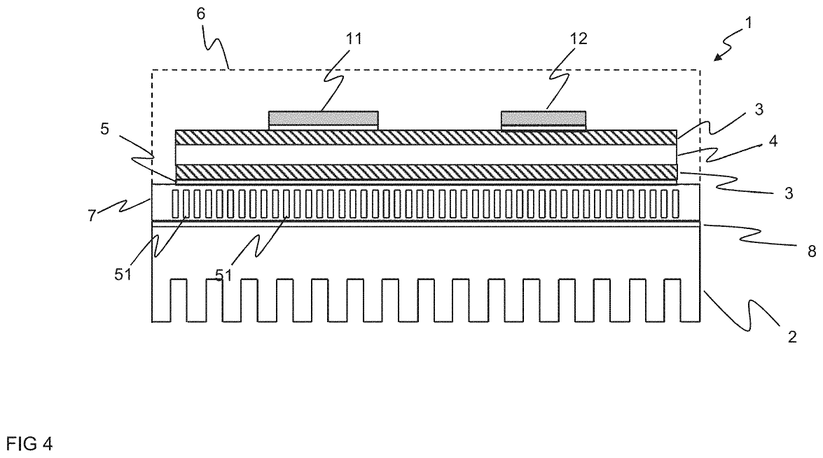

FIG. 4 shows another embodiment with the carbon based material plates 51 inside the base plate. The carbon based material plates are preferably graphite or graphene and may be synthetic or natural graphite or graphene. Further, the plates may be of pyrolytic graphene or graphite. FIG. 4 shows a cross section of the power electronics module and shows thus the height and width dimensions of the carbon based material plates. The plates or strips are arranged parallel to each other and they extend in the direction of the length of the power electronics module. As shown in FIG. 4, the plates 51 inside the metallic structure of the heat transfer structure are at a distance from each other. Further, the carbon based material plates are further evenly spaced inside the heat transfer structure. The corresponding parts of the module are numbered with the same number as in connection with FIG. 1. As mentioned, FIGS. 2 and 4 show embodiments in which the heat transfer structure of the disclosure is employed in a power electronics module.

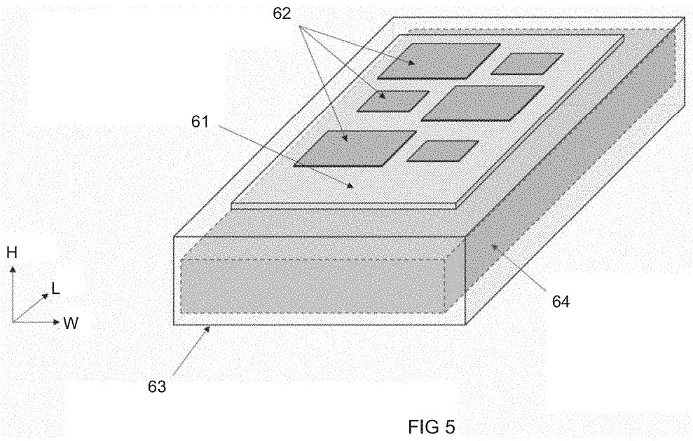

FIG. 5 shows a simplified perspective view of a power electronics module with six power electronics semiconductor components 62 on a substrate, such as a direct copper bonded structure 61. The DCB structure 61 is attached to a base plate 63 having a carbon based insert 64. The carbon based insert 64 is shown in simplified manner as a block. It is, however clear, that the core structure is, for example, formed of carbon based material plates which extend parallel in the direction of length L of the power electronics module.

The heat transfer structure of the disclosure may also employed as a cooling element comprising a heat receiving body. The heat receiving body is a metallic body having a first surface and a second surface, which surfaces are opposing surfaces. Further, in the cooling element of the disclosure, one of the first surface and the second surface is adapted to receive a heat generating component, and the metallic body comprises a carbon based insert. The structure of the cooling element of the disclosure corresponds to that of the base plate described above in detail. The cooling element may be heat sink having cooling fins for transferring the heat to surrounding air or a liquid cooled element in which a liquid, such as water, is circulated for removing the heat.

The heat transfer structure may also be structured as a combination of a cooling element and base plate of a power electronics module. In such a structure the heat transfer element is employed as a base plate of a power electronics module as described in detail above. Further, another surface of the metallic body may be furnished with cooling fins or openings for fluid, that can be either gas or liquid, circulation for removing heat from the base plate. In such a structure efficient thermal properties are obtained with a single structure, i.e. without separate cooling element attached to the base plate.

The carbon based material plates may be separate plates or strips which are arranged in parallel inside the metallic, preferably copper, base plate. The carbon based material plates may also be provided as a larger entity having two or multiple of plates attached to each other. For example, all of the carbon based material plates may be attached to each other in one end of the plates. The plates may be attached to each other also from the center of the plates or in any other position of the plates.

The bottom surface of the base plate is adapted to receive a cooling device in thermally conductive manner such that the heat from the semiconductor components or chips is led through the base plate to the cooling device such as a heat sink. As the heat is spread effectively in the base plate, the cooling device does not have to be as effective as in the case with the known base plates. Use of a separate cooling device may also be used although above described combination of base plate and heat sink is possible.

According to an embodiment, the at least one power electronics component is an insulated gate bipolar transistor (IGBT). IGBT components are widely used in power electronics applications.

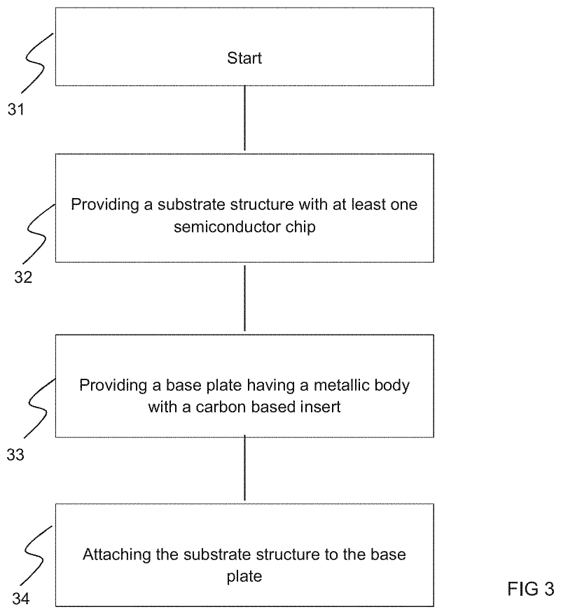

In the method of manufacturing a power electronics module and as shown in the flowchart of FIG. 3, a direct copper bonding structure which is a substrate structure with at least one semiconductor chip is provided 32. Further, a base plate having a metallic body with a carbon based insert is provided 33. Further, the substrate structure is attached 34, for example by soldering to a surface of the base plate. With the method of the invention, a power electronics module is obtained which has the benefits and properties described above.

According to an embodiment of the invention, the metallic body is a copper body. Further, according to a further embodiment, the carbon based insert is formed of carbon based material plates which are arranged parallel and at distance from another.

In the above, the invention is described in connection with a power electronics module. As it understood, the power electronics module of the disclosure comprises a base plate which is structured as a heat transfer structure of the present disclosure. Further, the cooling element of the disclosure comprises corresponding heat transfer structure as described in connection with the power electronics module.

It will be obvious to a person skilled in the art that, as the technology advances, the inventive concept can be implemented in various ways. The invention and its embodiments are not limited to the examples described above but may vary within the scope of the claims.

1. A heat transfer structure, wherein the structure comprises:
a metallic body having a first surface and a second surface, wherein the first surface and the second surface are opposing surfaces, one of the first surface and the second surface is adapted to receive a heat generating component, and wherein
the metallic body comprises a carbon based insert.

2. The heat transfer structure according to claim 1, wherein the carbon based insert has anisotropic thermal conductivity.

3. The heat transfer structure according to claim 2, wherein the thermal conductivity of the carbon based insert is highest in a plane defined by the directions of length and height of the metallic body, the direction of length being defined as the direction of the longest dimension of the metallic body and the direction of height being defined as the direction of normal of the first surface of metallic body.

4. The heat transfer structure according to claim 3, wherein the metallic body of the heat transfer structure is a copper structure and the carbon based insert comprises carbon based material plates arranged inside the copper structure.

5. The heat transfer structure according to claim 4, wherein the carbon based material plates have a length, a width and a height, the length being the greatest dimension and the height being the smallest dimension of the plates, wherein the carbon based material plates are arranged parallel inside the metallic body, such that the direction of length of carbon based material plates correspond to the direction of length of the metallic body and the direction of width of carbon based material plates correspond to the direction of height of the metallic body.

6. The heat transfer structure according to claim 4, wherein the carbon based material plates are of graphite or graphene.

7. The heat transfer structure according to claim 6, wherein the graphite or graphene is synthetic graphite or graphene.

8. The heat transfer structure according to claim 7, wherein the parallel arranged carbon based material plates are at a distance from each other and are connected to each other from one end of the plates.

9. A power electronics module comprising:
at least one power electronics component, wherein the power electronics module comprises a base plate for transferring heat generated by the at least one power electronics component to a cooling device, the base plate being a metallic body having a first surface and a second surface, wherein
the first surface and the second surface are opposing surfaces,
one of the first surface and the second surface is adapted to receive the at least one power electronics component, and wherein
the metallic body comprises a carbon based insert.

10. The power electronics module according to claim 9, wherein the carbon based insert has anisotropic thermal conductivity.

11. The power electronics module according to claim 10, wherein the thermal conductivity of the carbon based insert is highest in a plane defined by the directions of length and height of the base plate, the direction of length being defined as the direction of the longest dimension of the base plate and the direction of height being defined as the direction of normal of the surface of the base plate.

12. The power electronics module according to claim 11, wherein the metallic body of the base plate is a copper structure and the carbon based insert comprises carbon based material plates arranged inside the copper structure.

13. The power electronics module according to claim 12, wherein the carbon based material plates have a length, a width and a height, the length being the greatest dimension and the height being the smallest dimension of the plates, wherein the carbon based material plates are arranged parallel inside the metallic body of the base plate, such that the direction of length of carbon based material plates correspond to the direction of length of the metallic body and the direction of width of carbon based material plates correspond to the direction of height of the metallic body.

14. The power electronics module according to claim 12, wherein the carbon based material plates are of graphite or graphene.

15. The power electronics module according to claim 14, wherein the graphite or graphene is synthetic graphite or graphene.

16. The power electronics module according to claim 9, wherein the power electronics module comprises a substrate to which the at least one power electronics component is attached.

17. The power electronics module according to claim 16, wherein the substrate is a direct bonded copper structure.

18. The power electronics module according to claim 17, wherein the at least one power electronics component is an insulated gate bipolar transistor.

19. The power electronics module according to claim 13, wherein the parallel arranged carbon based material plates are at a distance from each other and are connected to each other from one end of the plates.

20. A cooling element comprising:
a heat receiving body, wherein the heat receiving body is a metallic body having a first surface and a second surface, wherein
the first surface and the second surface are opposing surfaces,
one of the first surface and the second surface is adapted receive a heat generating component, and
the metallic body comprises a carbon based insert.

21. The cooling element according to claim 20, wherein the carbon based insert has anisotropic thermal conductivity.

22. The cooling element according to claim 21, wherein the thermal conductivity of the carbon based insert is highest in a plane defined by the directions of length and height of the metallic body, the direction of length being defined as the direction of the longest dimension of the metallic body and the direction of height being defined as the direction of normal of the surface of the metallic body.

23. The cooling element according to claim 22, wherein the metallic body of the cooling element is a copper structure and the carbon based insert comprises carbon based material plates arranged inside the copper structure.

24. The cooling element according to claim 23, wherein the carbon based material plates have a length, a width and a height, the length being the greatest dimension and the height being the smallest dimension of the plates, wherein the carbon based material plates are arranged parallel inside the metallic body of the cooling element, such that the direction of length of carbon based material plates correspond to the direction of length of the metallic body and the direction width of carbon based material plates correspond to the direction of height of the metallic body.

25. The cooling element according to claim 20, wherein another one of the first surface and the second surface comprises cooling fins and/or openings for fluid circulation.

26. A method of manufacturing a heat transfer structure, the method comprising
providing a metallic body having a first surface and a second surface, the first surface and the second surface are opposing surfaces, and one of the first surface and the second surface is adapted to receive a heat generating component, and
providing a carbon based insert in the metallic body.

27. A method of manufacturing a power electronics module, the method comprising
providing a substrate structure with at least one semiconductor chip,
providing a base plate having a metallic body with a carbon based insert, and
attaching the substrate structure to the base plate.

28. The method of manufacturing a power electronics module according to claim 26, wherein the metallic structure is a copper structure.

29. The method of manufacturing a power electronics module according to claim 27, wherein the carbon based core structure is formed of carbon based material plates which are arranged parallel and at distance from another.

30. The heat transfer structure according to claim 5, wherein the carbon based material plates are of graphite or graphene.

31. The heat transfer structure according to claim 30, wherein the graphite or graphene is synthetic graphite or graphene.

32. The heat transfer structure according to claim 31, wherein the parallel arranged carbon based material plates are at a distance from each other and are connected to each other from one end of the plates.

33. The power electronics module according to claim 13, wherein the carbon based material plates are of graphite or graphene.

34. The power electronics module according to claim 33, wherein the graphite or graphene is synthetic graphite or graphene.

35. The cooling element according to claim 24, wherein another one of the first surface and the second surface comprises cooling fins and/or openings for fluid circulation.
